(19) United States
(12) Patent Application Publication
(10) Pub. No.: US 2021/0226142 A1
(43) Pub. Date: Jul. 22, 2021

(54) UV CROSSLINKING OF PVDF-BASED POLYMERS FOR GATE DIELECTRIC INSULATORS OF ORGANIC THIN-FILM TRANSISTORS

(71) Applicant: CORNING INCORPORATED, Corning, NY (US)

(72) Inventors: Mingqian He, Horseheads, NY (US); Xin Li, Shanghai (CN); Yang Li, Shanghai (CN); Hongxiang Wang, Shanghai (CN)

(21) Appl. No.: 17/268,528

(22) PCT Filed: Aug. 5, 2019
(86) PCT No.: PCT/US2019/045112

§ 371 Date: Feb. 15, 2021

(30) Foreign Application Priority Data
Aug. 17, 2018 (CN) 201810940323.7

(51) Int. Cl. H01L 51/05; H01L 51/00; C08F 2/50; C08F 214/22; C08F 214/28; C08K 5/28

(52) U.S. Cl. CPC H01L 51/052; H01L 51/0545; H01L 51/0007; C08K 5/28; C08F 2/50; C08F 214/22; C08F 214/28; H01L 51/0034

(57) ABSTRACT

A method includes preparing a mixture having an organic solvent, a fluorine-containing polymer, at least one organic base, and a crosslinker component; depositing the mixture over a substrate to form a first layer; and crosslinking the first layer by light treatment to form a crosslinked gate dielectric layer, such that the fluorine-containing polymer is at least one of homopolymers of vinylidene fluoride or copolymers of vinylidene fluoride with fluorine-containing ethylenic monomers. A transistor includes a crosslinked gate dielectric layer disposed over a substrate; an organic semiconductor layer disposed over the substrate and being in direct contact with the crosslinked gate dielectric layer; a source and a drain in contact with the organic semiconductor layer and defining the ends of a channel through the organic semiconductor layer; and a gate superposed with the channel, such that the crosslinked gate dielectric layer separates the gate from the organic semiconductor layer.

### BACKGROUND

This application claims the benefit of priority under 35 U.S.C. § 119 of Chinese Patent Application Serial No. 201810940323.7, filed on Aug. 17, 2018, the content of which is relied upon and incorporated herein by reference in its entirety.

### 1. Field

The disclosure relates to UV crosslinking of PVDF-based polymers for gate dielectric insulators of organic thin-film transistors (OTFTs).

### 2. Technical Background

Organic thin-film transistors (OTFTs) have garnered extensive attention as alternatives to conventional silicon-based technologies, which require high temperature and high vacuum deposition processes, as well as complex photolithographic patterning methods. Gate dielectric insulators are one important component of OTFTs which can effectively influence the performance of devices.

Emerging applications require gate dielectrics having high dielectric constants, high dielectric strengths, high mechanical strengths, and uniform surface properties. Traditional inorganic gate dielectrics (i.e., silicon oxide) exhibit high Young's modulus to impede their flexibility. Moreover, currently available organic gate dielectrics require thermal curing processes unacceptable for practical industrial application (e.g., six hours at 180° C.).

This disclosure presents improved PVDF-based polymers for gate dielectrics of organic thin-film transistors and methods of manufacturing thereof.

### SUMMARY

In some embodiments, a method comprises: preparing a mixture comprising: an organic solvent, a fluorine-containing polymer, at least one organic base, and a crosslinker component; depositing the mixture over a substrate to form a first layer; crosslinking the first layer by light treatment to form a crosslinked gate dielectric layer, wherein the fluorine-containing polymer is at least one of homopolymers of vinylidene fluoride, copolymers of vinylidene fluoride with fluorine-containing ethylenic monomers, or a combination thereof.

In one aspect, which is combinable with any of the other aspects or embodiments, the fluorine-containing polymer is a copolymer of vinylidene fluoride with at least one fluorine-containing ethylenic monomers.

In one aspect, which is combinable with any of the other aspects or embodiments, the at least one fluorine-containing ethylenic monomers are represented by Formula (1) or Formula (2):

CF₂═CF—R_{f1} Formula (1)

wherein R_{f1} is selected from: —F; —CF₃; and —OR_{f2}; and R_{f2} is a perfluoroalkyl group having 1 to 5 carbon atoms;

CX₂═CY—R_{f3} Formula (2)

wherein X is —H, or —F, or a halogen atom; Y is —H, or —F, or a halogen atom; and R_{f3} is —H, or —F, a perfluoroalkyl group having 1 to 5 carbon atoms, or a polyfluoroalkyl group having 1 to 5 carbon atoms.

In one aspect, which is combinable with any of the other aspects or embodiments, the at least one fluorine-containing ethylenic monomers are selected from: tetrafluoroethylene (TFE), chlorotrifluoroethylene (CTFE), trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

In one aspect, which is combinable with any of the other aspects or embodiments, the fluorine-containing polymer is poly(vinylidene fluoride-co-hexafluoropropylene) (PVDF-HFP).

In one aspect, which is combinable with any of the other aspects or embodiments, the at least one organic base has the structure:

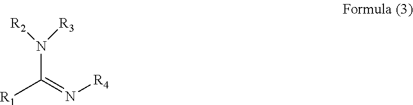

wherein the at least one organic base has a molecular weight of 1000 or less; R₁ and R₂ form a C₂-C₁₂ alkylene bridge, or independently of one another are C₁-C₁₂ alkyls; R₃ and R₄, independent from R₁ and R₂, form a C₂-C₁₂ bridge, or independently of one another are C₁-C₁₈ alkyls.

In one aspect, which is combinable with any of the other aspects or embodiments, the at least one organic base is selected from: 1,8-diazabicyclo[5.4.0]undec-7-ene, (DBU); 1,5-diazabicyclo[4.3.0]non-5-ene, (DBN); tetramethylguanidine, (TMG); triethylamine, (TEA); hexamethylenediamine, (HMDA); methylamine; dimethylamine; ethylamine; azetidine; isopropylamine; propylamine; 1.3-propanediamine; pyrrolidine; N,N-dimethylglycine; butylamine; tert-butylamine; piperidine; choline; hydroquinone; cyclohexylamine; diisopropylamine; saccharin; o-cresol; δ-ephedrine; butylcyclohexylamine; undecylamine; 4-dimethylaminopyridine (DMAP); diethylenetriamine; 4-aminophenol; or combinations thereof.

In one aspect, which is combinable with any of the other aspects or embodiments, the at least one organic base is 1,8-diazabicyclo[5.4.0]undec-7-ene, (DBU).

In one aspect, which is combinable with any of the other aspects or embodiments, the crosslinker component is an aryl azide.

In one aspect, which is combinable with any of the other aspects or embodiments, the aryl azide is selected from phenyl azides, hydroxyphenyl azides, and nitrophenyl azides.

In one aspect, which is combinable with any of the other aspects or embodiments, the aryl azide comprises: 2,6-bis(4-azidobenzylidene) cyclohexanone; 1,3,5-tris(azidomethyl)-2,4,6-triethyl benzene; phenyl azide; o-hydroxyphenyl azide; m-hydroxyphenyl azide; tetrafluorophenyl azide; o-nitrophenyl azide; m-nitrophenyl azide; azido-methyl coumarin; N-(5-azido-2-nitrobenzoyloxy) succinimide; N-hydroxysuccinimidyl-4-azidobenzoate; p-azidophenacyl bromide; 4-azido-2,3,5,6-tetrafluorobenzoic acid; N-succinimidyl 4-azido-2,3,5,6-tetrafluorobenzoate; bis[2-(4-azidosalicylamido)ethyl] disulfide; 2-[N2-(4-azido-2,3,5,6-tetrafluorobenzoyl)-N6-(6-biotinamidocaproyl)-L-lysinyl]ethyl 2-carboxyethyl disulfide; 2-[N2-(4-azido-2,3,5,6-tetrafluorobenzoyl)-N6-(6-biotinamidocaproyl)-L-lysinyl]ethyl methanethiosulfonate; 2-{N2-[N6-(4-Azido-2,3,5,6-tetrafluorobenzoyl)-6-aminocaproyl]-N6-(6-biotinamidocaproyl)-L-lysinylamido}] ethyl 2-carboxyethyl disulfide; 2-{N2-[N6-(4-azido-2,3,5,6-tetrafluorobenzoyl)-6-aminocaproyl]-N6-(6-biotinamidocaproyl)-L-lysinylamido}ethyl methanethiosulfonate; 2-[N2-(4-azido-2,3,5,6-tetrafluorobenzoyl)-N6-(6-biotinamidocaproyl)-L-lysinyl]ethyl 2′-(N-sulfosuccinimidylcarboxy) ethyl disulfide, sodium salt; 6-(4-azido-2-nitrophenylamino)hexanoic acid N-hydroxysuccinimide ester; N-succinimidyl 4-azidosalicylate; sulphosuccinimidyl 6-(4′-azido-2′-nitrophenylamino) hexanoate; S-[2-(4-azidosalicylamido) ethylthio]-2-thiopyridine; S-[2-(iodo-4-azidosalicylamido) ethylthio]-2-thiopyridine; 3-[[2-[(4-azido-2-hydroxybenzoyl)amino]ethyl]dithio]propanoic acid 2,5-dioxo-3-sulfo-1-pyrrolidinyl ester sulfo-N-succinimidyl3-[[2-(p-azidosalicylamido)ethyl]-1,3′-dithio]propionate, or combinations thereof.

In one aspect, which is combinable with any of the other aspects or embodiments, the crosslinker component is 2,6-bis(4-azidobenzylidene) cyclohexanone.

In one aspect, which is combinable with any of the other aspects or embodiments, the crosslinker component is 1,3,5-tris(azidomethyl)-2,4,6-triethyl benzene.

In one aspect, which is combinable with any of the other aspects or embodiments, the organic solvent is selected from methyl ethyl ketone (MEK) and tetrahydrofuran (THF).

In one aspect, which is combinable with any of the other aspects or embodiments, the crosslinking the first layer by light treatment comprises exposing the first layer to ultraviolet (UV) light for a time in a range of 10 sec to 60 min.

In one aspect, which is combinable with any of the other aspects or embodiments, the crosslinking the first layer by light treatment comprises exposing the first layer to ultraviolet (UV) light to a total energy in a range of 5 J to 2600 J.

In one aspect, which is combinable with any of the other aspects or embodiments, the first layer is exposed for a time not exceeding 10 min.

In one aspect, which is combinable with any of the other aspects or embodiments, the method further comprises: depositing an organic semiconductor over the substrate to form a second layer, the second layer being in direct contact with the crosslinked gate dielectric layer; forming a source and a drain in contact with the second layer, the source and drain defining the ends of a channel through the second layer; and forming a gate superposed with the channel to form a transistor, wherein the crosslinked gate dielectric layer separates the gate from the second layer.

In some embodiments, a transistor comprises: a substrate; a crosslinked gate dielectric layer disposed over the substrate; an organic semiconductor layer disposed over the substrate, the organic semiconductor layer being in direct contact with the crosslinked gate dielectric layer; a source and a drain in contact with the organic semiconductor layer the source and drain defining the ends of a channel through the organic semiconductor layer; and a gate superposed with the channel, wherein the crosslinked gate dielectric layer separates the gate from the organic semiconductor layer.

In one aspect, which is combinable with any of the other aspects or embodiments, the crosslinked gate dielectric layer comprises: at least one organic base at a concentration in a range of 0.01 wt. % to 10 wt. %; and a crosslinker component at a concentration in a range of 0.01 wt. % to 10 wt. %.

In one aspect, which is combinable with any of the other aspects or embodiments, the at least one organic base is at a concentration in a range of 1 wt. % to 5 wt. %.

In one aspect, which is combinable with any of the other aspects or embodiments, the crosslinker component is at a concentration in a range of 2 wt. % to 8 wt. %.

In one aspect, which is combinable with any of the other aspects or embodiments, the crosslinked gate dielectric layer is configured to have a surface roughness in a range of 0.01 μm to 0.05 μm.

In one aspect, which is combinable with any of the other aspects or embodiments, the transistor is configured to have a charge mobility of at least 3.0 cm²V⁻¹s⁻¹.

In one aspect, which is combinable with any of the other aspects or embodiments, the transistor is configured to have an average on/off ratio of at least 3.00×10⁴.

In one aspect, which is combinable with any of the other aspects or embodiments, the crosslinked gate dielectric layer comprises one of a 2,6-bis(4-azidobenzylidene) cyclohexanone or 1,3,5-tris(azidomethyl)-2,4,6-triethyl benzene crosslinker component and at least one organic base.

### BRIEF DESCRIPTION OF THE DRAWINGS

The disclosure will become more fully understood from the following detailed description, taken in conjunction with the accompanying figures, in which:

FIG. 1 illustrates PVDF-CTFE samples crosslinked effectively with Azide A, according to some embodiments.

FIG. 2 illustrates PVDF-HFP samples not crosslinked effectively with Azide A, according to some embodiments.

FIG. 3 illustrates PVDF-HFP samples crosslinked effectively with DBU and Azide A, according to some embodiments.

FIG. 4 illustrates images of films with Azide A crosslinker component (upper) and Azide B crosslinker component (lower) in THF, according to some embodiments.

FIG. 5 illustrates an exemplary OTFT device, according to some embodiments.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments. It should be understood that the present application is not limited to the details or methodology set forth in the description or illustrated in the figures. It should also be understood that the terminology is for the purpose of description only and should not be regarded as limiting.

Additionally, any examples set forth in this specification are illustrative, but not limiting, and merely set forth some of the many possible embodiments of the claimed invention. Other suitable modifications and adaptations of the variety of conditions and parameters normally encountered in the field, and which would be apparent to those skilled in the art, are within the spirit and scope of the disclosure.

As stated above, OTFTs are particularly interesting because their fabrication processes are less complex as compared with conventional silicon-based technologies. For example, OTFTs generally rely on low temperature deposition and solution processing, which, when used with semiconducting conjugated polymers, can achieve valuable technological attributes, such as compatibility with simple-write printing techniques, general low-cost manufacturing approaches, and flexible plastic substrates. Other potential applications for OTFTs include flexible electronic papers, sensors, memory devices (e.g., radio frequency identification cards (RFIDs)), remote controllable smart tags for supply chain management, large-area flexible displays, and smart cards.

Gate dielectric insulators are one important component of OTFTs which can effectively influence the performance of devices. Polymeric gate dielectrics are advantageous due to their flexibility and compatibility with organic semiconductors. For example, organic gate dielectric layers may be manufactured using cost-effective solution processing at ambient temperature, thereby enabling fabrication of organic electronic devices on plastic or paper-based flexible substrates. Moreover, organic gate dielectrics may also have lower leakage currents than their inorganic counterparts.

Fluoroelastomers (e.g., PVDF-HFP, PVDF-CTFE, etc.) are highly fluorinated polymers which may be particularly suited as organic gate dielectric materials because they are extremely resistant to oxidative attack, flame, chemicals, solvents and compression set. Their stability may be attributed to the strength of the carbon-fluorine bond (as compared to that of the carbon-carbon bond), steric hindrance, and strong van der Waals forces. However, in order to be effective organic gate dielectric materials, fluoroelastomers need to have sufficient mechanical stability and are thus cured at high temperatures (e.g., at least 180° C.) and long durations (e.g., up to 6 hours). These curing conditions are unacceptable for practical industrial applications.

The present disclosure describes materials and photo-crosslinking methods thereof as one efficient means for improving the polymers' mechanical and dielectric strength. Photo-crosslinkable material can, in principle, avoid using complicated and non-environmentally friendly photolithography by providing a facile and low-cost method for fabricating patterned layers in microelectronic devices.

More particularly, a UV-crosslinkable gate dielectric insulator formulation is disclosed comprising poly(vinylidene fluoride-co-hexafluoropropylene) (PVDF-HFP), at least one organic base and crosslinker components (e.g., azide-based). Double bonds of PVDF-HFP were effectively crosslinked by nitrene intermediates (see Reaction 1 below), which were released by the azide-based crosslinker component under UV-light in inert atmosphere. The reaction schemes below describe the response of azide-based crosslinker components upon exposure to UV-light and possible subsequent general reactions of nitrene used as a crosslinking agent.

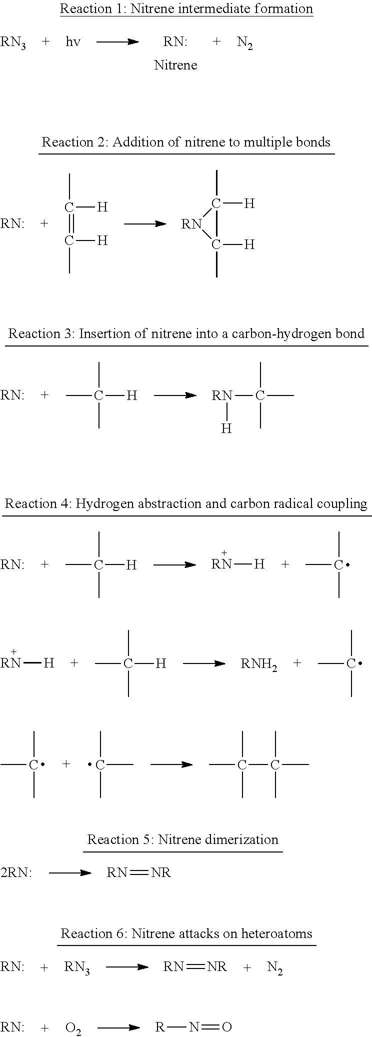

Crosslinking of the fluoroelastomer is aided by the presence of at least one organic base and azide-based crosslinker components, whereby the process is conducted for a time in a range of 10 sec to 60 min, without heating as compared to curing for six hours and at up to 180° C. according to traditional methods. Thus, the disclosed process is more controllable and effective, with the UV-crosslinking significantly improving surface quality of subsequently-fashioned gate dielectric films made of fluoroelastomers (e.g., color, surface roughness, pinholes, etc.). The UV-crosslinked fluoroelastomer preserves double-layer capacitor effect, while achieving high charge mobility, on/off ratio, and transconductance, as well as a steady threshold voltage device performance.

In some examples, a layer of crosslinked fluorine-containing polymer may be prepared by preparing a mixture comprising: an organic solvent, a fluorine-containing polymer, at least one organic base, and a crosslinker component; depositing the mixture over a substrate to form a first layer; and crosslinking the first layer by light treatment to form a crosslinked gate dielectric layer.

### Organic Solvent

In some examples, the organic solvent may be selected from acetic acid, acetone, acetonitrile, benzene, 1-butanol, 2-butanol, 2-butanone (methyl ethyl ketone (MEK)), t-butyl alcohol, carbon tetrachloride, chlorobenzene, chloroform, cyclohexane, 1,2-dichloroethane, diethylene glycol, diethyl ether, diglyme (diethylene glycol dimethyl ether), 1,2-dimethoxyethane (glyme, DME), dimethyl formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphorous triamide (HMPT), hexane, methanol, methyl t-butyl ether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, o-xylene, m-xylene, and p-xylene.

In some examples, the organic solvent is methyl ethyl ketone (MEK). In some examples, the organic solvent is tetrahydrofuran (THF).

### Fluorine-Containing Polymer

In some examples, the fluorine-containing polymer is at least one of homopolymers of vinylidene fluoride, copolymers of vinylidene fluoride with fluorine-containing ethylenic monomers, or a combination thereof. In some examples, the fluorine-containing polymer is a copolymer of vinylidene fluoride with at least one fluorine-containing ethylenic monomers.

In some examples, the at least one fluorine-containing ethylenic monomers are represented by Formula (1) or Formula (2):

CF₂═CF—R_{f1} Formula (1)

where R_{f1} is selected from: —F; —CF₃, and —OR_{f2}; and R_{f2} is a perfluoroalkyl group having 1 to 5 carbon atoms; or

CX₂═CY—R_{f3} Formula (2)

wherein X is —H, or —F, or a halogen atom; Y is —H, or —F, or a halogen atom; and R_{f3} is —H, or —F, a perfluoroalkyl group having 1 to 5 carbon atoms, or a polyfluoroalkyl group having 1 to 5 carbon atoms.

In some examples, the at least one fluorine-containing ethylenic monomers are selected from: tetrafluoroethylene (TFE), chlorotrifluoroethylene (CTFE), trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

In some examples, the fluorine-containing polymer is poly(vinylidene fluoride-co-hexafluoropropylene) (PVDF-HFP), as shown below.

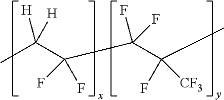

In some examples, the fluorine-containing polymer is poly(vinylidene fluoride-chlorotrifluoroethylene) (PVDF-CTFE), as shown below.

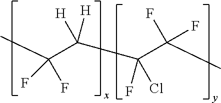

As defined herein, “perfluoroalkyl group” is broadly defined as aliphatic substances for which all of the H atoms attached to C atoms in the nonfluorinated substance from which they are notionally derived have been replaced by F atoms, except those H atoms whose substitution would modify the nature of any functional groups present. Moreover, as defined herein, “polyfluoroalkyl group” is broadly defined as aliphatic substances for which all H atoms attached to at least one (but not all) C atoms have been replaced by F atoms, in such a manner that they contain the perfluoroalkyl moiety CₙF₂ₙ₊₁.

### Organic Base

In the mixture described above at least one organic base is added. In some examples, the organic base has a pKa of 10-14 to significantly accelerate crosslinking of the fluorine-containing polymer. Compared to similar crosslinking procedures without use of organic bases, the method with organic bases decreases crosslinking time by up to 80% while simultaneously decreasing crosslinking temperature by up to 30° C. Without being bound by theory, it is believed that using an organic base with a pKa of 10 to 14 leads to a crosslinked network having a crosslinking density suitable for unexpectedly superior performance as a double-layer dielectric material. Moreover, it is believed that bases with pKa values lower than 10 would be not strong enough to create the desired C═C double bonds in the polymer backbone, and so may not have a sufficient accelerating effect. Bases with pKa values higher than 14 may preferentially scissor polymers chains rather than the desired C═C double bonds.

As used herein, the “pKa” of an organic base or other compound is the acid dissociation constant of that compound measured on a log scale (also known as pKa) at 25° C. It is appreciated that the pKa of a compound may be temperature dependent, and that some of the processes described herein take place at temperatures other than 25° C. Nevertheless, for purposes of determining whether a compound meets the pKa criteria described herein, the pKa of the compound at 25° C. should be compared to the ranges described herein. For example, where the criteria for selecting a suitable organic base is that the base has a pKa of 10 to 14, the pKa of the organic base at 25° C. should be compared to the range 10 to 14 to determine if the base is suitable, even if the process in which the organic base is used involves temperatures other than 25° C. Unless otherwise specified, pKa as described herein is measured in water.

In some examples, the organic base may have a pKa of 10, 11, 12, 13 or 14, or any range having any two of these values as endpoints. In some examples, the organic base has a pKa of 10 to 14. In some embodiments, the organic base has a pKa of 12 to 14.

In some examples, the at least one organic base has the structure:

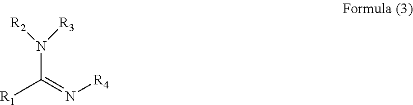

wherein the at least one organic base has a molecular weight of 1000 or less; R₁ and R₂ form a C₂-C₁₂ alkylene bridge, or independently of one another are C₁-C₁₈ alkyls; R₃ and R₄, independent from R₁ and R₂, form a C₂-C₁₂ bridge, or independently of one another are C₁-C₁₈ alkyls. Organic bases having Formula (3) include those of Table 1:

TABLE 1

| Structure | Name | CAS No. |
|---|---|---|
| 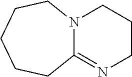 [SMILES: C1CCC2=NCCCN2CC1] | 2,3,4,6,7,8,9,10-octahydropyrimido[1,2- a]azepine | 6674-22-2 |
| 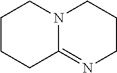 | 3,4,6,7,8,9-hexahydro-2H-pyrido[1,2- a]pyrimidine | 19616-52-5 |
| 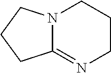 | 2,3,4,6,7,8-hexahydropyrrolo[1,2- a]pyrimidine | 3001-72-7 |
| 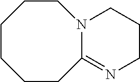 [SMILES: C1CCCN2CCCN=C2CC1] | 3,4,6,7,8,9,10,11-octahydro-2H- pyrimido[1,2-a]azocine | 58379-23-0 |
| 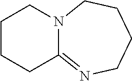 [SMILES: C1CCN2CCCCC2=NC1] | 2,3,4,5,7,8,9,10-octahydropyrido[1,2- a][1,3]diazepine | 106872-83-7 |
| 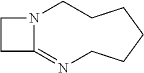 [SMILES: C1CCCN2CC/C2=N/CC1] | (Z)-1,8-diazabicyclo[7.2.0]undec-8-ene | 341497-13-0 |
| 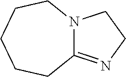 | 2,5,6,7,8,9-hexahydro-3H-imidazo[1,2- a]azepine | 7140-57-0 |
| 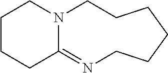 [SMILES: C1CCCN2CCCC/C2=N/CC1] | (Z)-2,3,4,5,6,7,9,10,11,12- decahydropyrido[1,2-a][1,3]diazonine | 341497-16-3 |
| 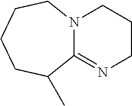 | 10-methyl-2,3,4,6,7,8,9,10- octahydropyrimido[1,2-a]azepine | 957494-36-9 |
| 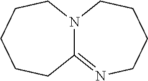 [SMILES: C1CCC2=NCCCCN2CC1] | 2,4,5,7,8,9,10,11-octahydro-3H- azepino[1,2-a][1,3]diazepine | 52411-85-5 |
| 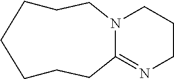 [SMILES: C1CCCC2=NCCCN2CCC1] | 2,3,4,6,7,8,9,10,11,12- decahydropyrimido[1,2-a]azonine | 6664-09-1 |
| 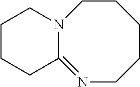 [SMILES: C1CC/N=C2/CCCCN2CC1] | (Z)-3,4,5,6,8,9,10,11-octahydro-2H- pyrido[1,2-a][1,3]diazocine | 850182-40-0 |
| 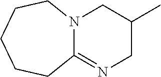 | 3-methyl-2,3,4,6,7,8,9,10- octahydropyrimido[1,2-a]azepine | 1330045-04-9 |
| 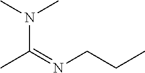 | (Z)-N,N-dimethyl-N′-propylacetimidamide | 94793-20-1 |
| 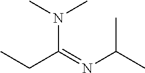 | (Z)-N′-isopropyl-N,N- dimethylpropionimidamide | 112752-57-5 |
| 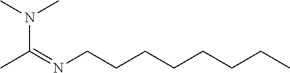 | (Z)-N,N-dimethyl-N′-octylacetimidamide | 103495-46-1 |

In some examples, the at least one organic base is selected from: 1,8-diazabicyclo[5.4.0]undec-7-ene, (DBU); 1,5-diazabicyclo[4.3.0]non-5-ene, (DBN); tetramethylguanidine, (TMG); triethylamine, (TEA); hexamethylenediamine, (HMDA); methylamine; dimethylamine; ethylamine; azetidine; isopropylamine; propylamine; 1.3-propanediamine; pyrrolidine; N,N-dimethylglycine; butylamine; tert-butylamine; piperidine; choline; hydroquinone; cyclohexylamine; diisopropylamine; saccharin; o-cresol; δ-ephedrine; butylcyclohexylamine; undecylamine; 4-dimethylaminopyridine (DMAP); diethylenetriamine; 4-aminophenol; or combinations thereof. Selected structures of the organic bases are disclosed here are shown in Table 2 below.

TABLE 2

| Structure | Name | CAS No. | pKa (25° C., 1 atm) |
|---|---|---|---|
| 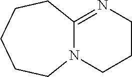 [SMILES: C1CCC2=NCCCN2CC1] | 1,8-Diazabicyclo[5.4.0] undec-7-ene, DBU | 6674-22-2 | 13.5 ± 1.5 water), 24.34 (acetonitrile) |
| 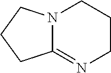 | 1,5-Diazabicyclo[4.3.0] non-5-ene, DBN | 3001-72-7 | 13.42 ± 0.20 |
| 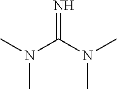 | Tetramethylguanidine, TMG | 80-70-6 | 13.0 ± 1.0 (water) |
| 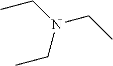 | Triethylamine, TEA | 121-44-8 | 10.75 (water), 9.00 (DMSO) |
| 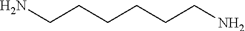 | Hexamethylenediamine, HMDA | 124-09-4 | 10.92 ± 0.10 |

In some examples, the at least one organic base is 1,8-diazabicyclo[5.4.0]undec-7-ene, (DBU), either alone or in combination with other organic bases. Each of the organic bases disclosed herein are suitable for use in the processes of the present application.

In some examples, the at least one organic base is present in the crosslinked gate dielectric layer at a concentration in a range of 0.01 wt. % to 10 wt. %, or in a range of 1 wt. % to 7 wt. %, or in a range of 1 wt. % to 5 wt. %, or in a range of 2 wt. % to 5 wt. %, or in a range of 2 wt. % to 4 wt. % (e.g., 3 wt. %).

### Crosslinker Component

As described above, an azide-based crosslinker component is included in the mixture. The photolysis of organic azides results in N₂ loss, producing nitrenes as reactive intermediates (Reaction 1). For example, bis-aryldiazides photolyze to give bis-dinitrenes by sequentially absorbing two photons. Reaction 2 illustrates an addition of the nitrene intermediate to carbon-carbon double bonds to provide aziridines. Reaction 3 illustrates nitrene is inserted into a carbon-hydrogen bond to provide a secondary amine (only observed for singlet nitrenes). Reaction 4 illustrates a hydrogen abstraction and carbon radical coupling, which is the most common reaction of triplet nitrenes in solution, where the formed amino radical and carbon radical generally diffuse apart, and the amino radical abstracts a second hydrogen atom to provide a primary amine. Reactions 5 and 6 illustrate means for obtaining azo dyes via nitrene dimerization and attacking on heteroatoms, respectively.

In some examples, the crosslinker component is an aryl azide such as at least one of phenyl azides, hydroxyphenyl azides, nitrophenyl azides, or combinations thereof.

In one aspect, which is combinable with any of the other aspects or embodiments, the aryl azide comprises: 2,6-bis(4-azidobenzylidene) cyclohexanone; 1,3,5-tris(azidomethyl)-2,4,6-triethyl benzene; phenyl azide; o-hydroxyphenyl azide; m-hydroxyphenyl azide; tetrafluorophenyl azide; o-nitrophenyl azide; m-nitrophenyl azide; azido-methyl coumarin; N-(5-azido-2-nitrobenzoyloxy) succinimide; N-hydroxysuccinimidyl-4-azidobenzoate; p-azidophenacyl bromide; 4-azido-2,3,5,6-tetrafluorobenzoic acid; N-succinimidyl 4-azido-2,3,5,6-tetrafluorobenzoate; bis[2-(4-azidosalicylamido)ethyl] disulfide; 2[N2-(4-azido-2,3,5,6-tetrafluorobenzoyl)-N6-(6-biotinamidocaproyl)-L-lysinyl]ethyl 2-carboxyethyl disulfide; 2-[N2-(4-azido-2,3,5,6-tetrafluorobenzoyl)-N6-(6-biotinamidocaproyl)-L-lysinyl]ethyl methanethiosulfonate; 2-{N2-[N6-(4-Azido-2,3,5,6-tetrafluorobenzoyl)-6-aminocaproyl]-N6-(6-biotinamidocaproyl)-L-lysinylamido}] ethyl 2-carboxyethyl disulfide; 2-{N2-[N6-(4-azido-2,3,5,6-tetrafluorobenzoyl)-6-aminocaproyl]-N6-(6-biotinamidocaproyl)-L-lysinylamido}ethyl methanethiosulfonate; 2-[N2-(4-azido-2,3,5,6-tetrafluorobenzoyl)-N6-(6-biotinamidocaproyl)-L-lysinyl]ethyl 2′-(N-sulfosuccinimidylcarboxy) ethyl disulfide, sodium salt; 6-(4-azido-2-nitrophenylamino)hexanoic acid N-hydroxysuccinimide ester; N-succinimidyl 4-azidosalicylate; sulphosuccinimidyl 6-(4′-azido-2′-nitrophenylamino) hexanoate; S-[2-(4-azidosalicylamido) ethylthio]-2-thiopyridine; S-[2-(iodo-4-azidosalicylamido) ethylthio]-2-thiopyridine; 3-[[2-[(4-azido-2-hydroxybenzoyl)amino]ethyl]dithio]propanoic acid 2,5-dioxo-3-sulfo-1-pyrrolidinyl ester sulfo-N-succinimidyl3-[[2-(p-azidosalicylamido)ethyl]-1,3′-dithio]propionate, or combinations thereof.

In some examples, the crosslinker component is 2,6-bis(4-azidobenzylidene) cyclohexanone. In some examples, the crosslinker component is 1,3,5-tris(azidomethyl)-2,4,6-triethyl benzene.

In some examples, the crosslinker component is present in the crosslinked gate dielectric layer at a concentration in a range of 0.01 wt. % to 10 wt. %, or in a range of 2 wt. % to 10 wt. %, or in a range of 2 wt. % to 8 wt. %, or in a range of 2 wt. % to 5 wt. %, or in a range of 5 wt. % to 8 wt. %.

After the mixture comprising the organic solvent, the fluorine-containing polymer, the at least one organic base, and the crosslinker component has been prepared and deposited over the substrate to form a first layer, the first layer may be crosslinked by light treatment to form a crosslinked gate dielectric layer. In some examples, light treatment comprises exposing the first layer to ultraviolet (UV) light for a time in a range of 10 sec to 60 min. In some examples, light treatment comprises exposing the first layer to ultraviolet (UV) light to a total energy in a range of 5 J to 2600 J.

In some examples, the UV light may have a wavelength in a range of 10 nm to 400 nm. In some examples, the UV light may be a shortwave UV light having a wavelength in a range of 100 nm to 280 nm, or a middle wave UV light having a wavelength in a range of 280 nm to 315 nm, or a longwave UV light having a wavelength in a range of 315 nm to 400 nm. In some examples, the UV light may be at a wavelength of 254 nm or 365 nm. In some examples, the light treatment is conducted at a time in a range of 5 min to 45 min, or in a range of 5 min to 30 min, or in a range of 5 min to 25 min, or in a range of 5 min to 20 min, or in a range of 5 min to 15 min, or in a range of 5 min to 10 min. In some examples, the light treatment is conducted for a time not exceeding 10 min.

UV crosslinking of gate dielectric layers aides to simplify processing of TFT array manufacturing. High performance OTFTs require organic gate dielectrics to have uniform surfaces, low leakage current densities, and photo-patternability with high patterning resolution. Azide-based crosslinker components may be applied as a portion of fluorine-containing polymer-based gate dielectric insulators for OTFTs.

After forming the crosslinked gate dielectric layer, an organic semiconductor (OSC) may be deposited over the substrate to form a second layer, the second layer being in direct contact with the crosslinked gate dielectric layer. In some examples, the OSC is positioned between the substrate and the crosslinked gate dielectric layer. In some examples, the crosslinked gate dielectric layer is positioned between the substrate and the OSC.

### Organic Semiconductor (OSC) Polymers

In some examples, the OSC polymer may comprise a diketopyrrolopyrrole-fused thiophene polymeric material. In some examples, the fused thiophene is beta-substituted. In some examples, the organic semiconductor polymer comprises the repeat unit of Formula (4) or Formula (5):

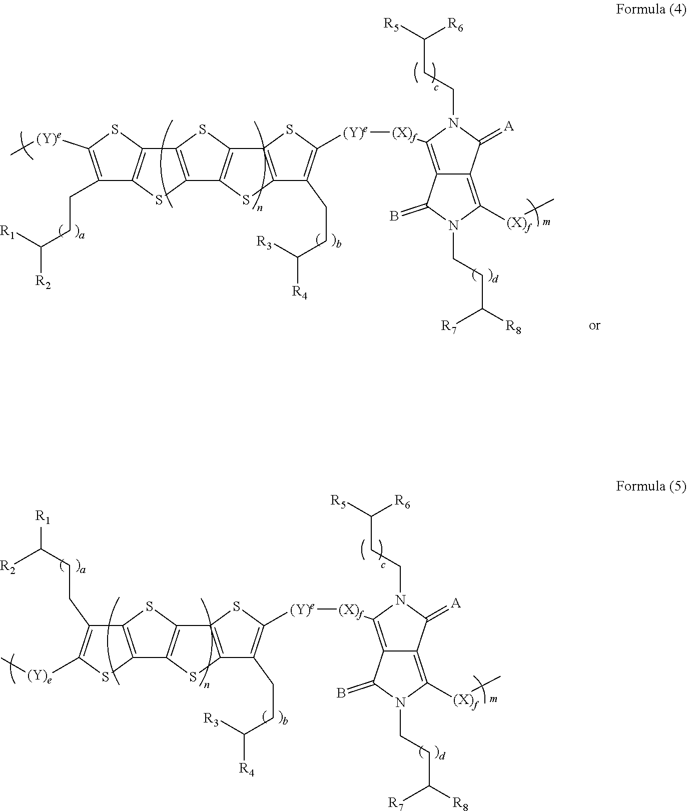

wherein, in Formula (4) and Formula (5), m is an integer greater than or equal to one; n is 0, 1, or 2; R₁, R₂, R₃, R₄, R₅, R₆, R₇, and R₈, may be, independently, hydrogen, substituted or unsubstituted C₄ or greater alkyl, substituted or unsubstituted C₄ or greater alkenyl, substituted or unsubstituted C₄ or greater alkynyl, or C₅ or greater cycloalkyl; a, b, c, and d are independently, integers greater than or equal to 3; e and f are integers greater than or equal to zero; X and Y are, independently a covalent bond, an optionally substituted aryl group, an optionally substituted heteroaryl, an optionally substituted fused aryl or fused heteroaryl group, an alkyne or an alkene; and A and B may be, independently, either S or O, with the provisos that:

i. at least one of R₁ or R₂; one of R₃ or R₄; one of R₅ or R₆; and one of R₇ or R₈ is a substituted or unsubstituted alkyl, substituted or unsubstituted alkenyl, substituted or unsubstituted alkynyl, or cycloalkyl;

ii. if any of R₁, R₂, R₃, or R₄ is hydrogen, then none of R₅, R₆, R₇, or R₈ are hydrogen;

iii. if any of R₅, R₆, R₇, or R₈ is hydrogen, then none of R₁, R₂, R₃, or R₄ are hydrogen;

iv. e and f cannot both be 0;

v. if either e or f is 0, then c and d, independently, are integers greater than or equal to 5; and

vi. the polymer having a molecular weight, wherein the molecular weight of the polymer is greater than 10,000.

In some examples, the OSC polymer is selected from PTDPPTFT4 (Formula (6)), poly(3-hexylthiophene-2,5-diyl) (P3HT), poly(isoindigo-bithiophene) (PII2T), graphene, or [6,6]-phenyl-C61-butyric acid methyl ester (PCBM).

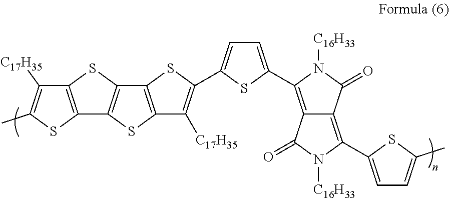

After formation of the OSC polymer second layer, a source and drain was formed to contact the second layer, with the source and drain defining the ends of a channel through the second layer; and thereafter, a gate was formed to superpose with the channel to form a transistor, wherein the crosslinked gate dielectric layer separates the gate from the second layer.

Thus, a transistor is formed and comprises a substrate; a crosslinked gate dielectric layer disposed over the substrate; an organic semiconductor layer disposed over the substrate, the organic semiconductor layer being in direct contact with the crosslinked gate dielectric layer; a source and a drain in contact with the organic semiconductor layer the source and drain defining the ends of a channel through the organic semiconductor layer; and a gate superposed with the channel, wherein the crosslinked gate dielectric layer separates the gate from the organic semiconductor layer.

In some examples, the crosslinked gate dielectric layer is configured to have a surface roughness in a range of 0.01 μm to 0.1 μm, or in a range of 0.01 μm to 0.07 μm, or in a range of 0.01 μm to 0.05 μm. In some examples, the transistor is configured to have a charge mobility of at least 0.5 cm²V⁻¹s⁻¹, or at least 1.0 cm²V⁻¹s⁻¹, or at least 1.5 cm²V⁻¹s⁻¹, or at least 2.0 cm²V⁻¹s⁻¹, or at least 2.5 cm²V⁻¹s⁻¹, or at least 3.0 cm²V⁻¹s⁻¹. In some examples, the transistor is configured to have an average on/off ratio of at least 1.00×10², or at least 5.00×10², or at least 1.00×10³, or at least 5.00×10³, or at least 7.00×10³, or at least 1.00×10⁴, or at least 1.50×10⁴, or at least 2.00×10⁴, or at least 3.50×10⁴.

### EXAMPLES

The embodiments described herein will be further clarified by the following examples.

### Example 1: UV-Crosslinking of PVDF-CTFE Copolymers with 2,6-bis(4-azidobenzylidene) cyclohexanone (“Azide A”) Crosslinker Component

Two sample mixtures were prepared to test the mechanical stability of PVDF-CTFE with and without Azide A crosslinker component. In sample 1, PVDF-CTFE was dissolved in 2-butanone (MEK) and methylene dichloride (DCM), spin-coated onto a glass substrate, and then exposed to UV light for 30 min in N2 atmosphere. No Azide A was included in sample 1. Sample 2 was prepared as sample 1, with the addition of Azide A in the mixture prior to spin-coating onto the substrate. Preparation conditions are summarized in Table 3.

TABLE 3

| | Sample 1 | | Sample 2 | |
|---|---|---|---|---|
| PVDF-CTFE | 1.2 | g | 1.2 | g |
| MEK | 8 | mL | 8 | mL |
| Azide A | — | | 10% (120 mg) | |
| DCM | 4 | mL | 4 | mL |
| Spin coating | 2000 rpm, 60 sec, 2000 | | 2000 rpm, 60 sec, 2000 | |
| | rpm/sec | | rpm/sec | |
| UV irradiation | 30 | min | 30 | min |
| (254 nm) | | | | |

| | | |
|---|---|---|
| Soaking (MEK) | overnight | overnight |
| Result | soluble | insoluble |

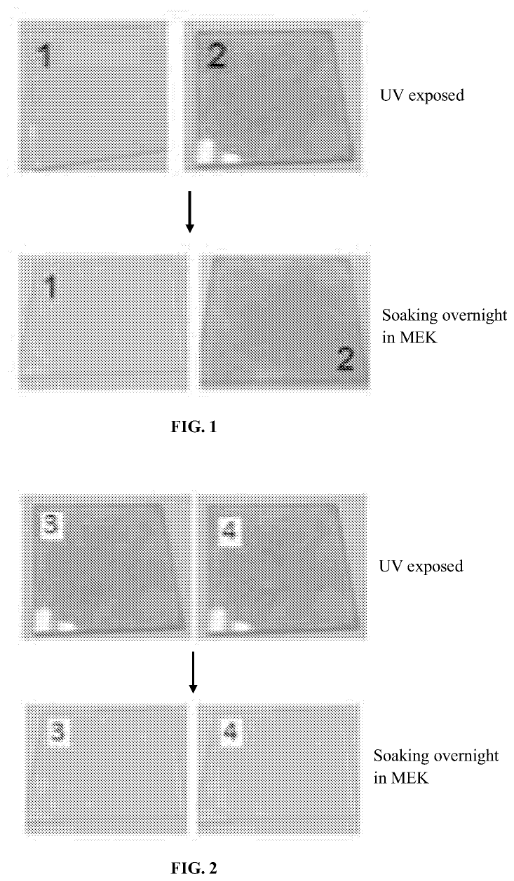

Both samples were soaked in MEK overnight. Sample 2 was insoluble in MEK, indicating that the PVDF-CTFE was crosslinked effectively with Azide A as a crosslinker under UV light in nitrogen atmosphere. Without being bound by theory, Reactions 7-9 describe one mechanism by which Azide A may possibly crosslink PVDF-CTFE while FIG. 1 illustrates solubility results of soaking sample 1 and sample 2 in MEK overnight.

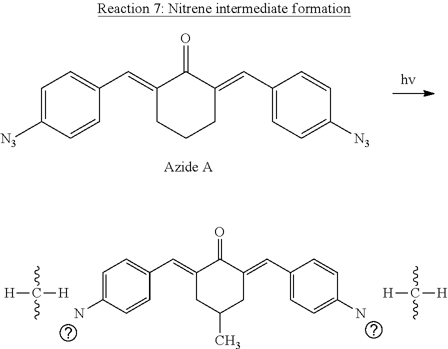

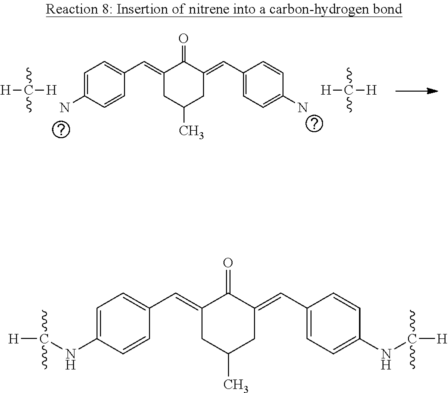

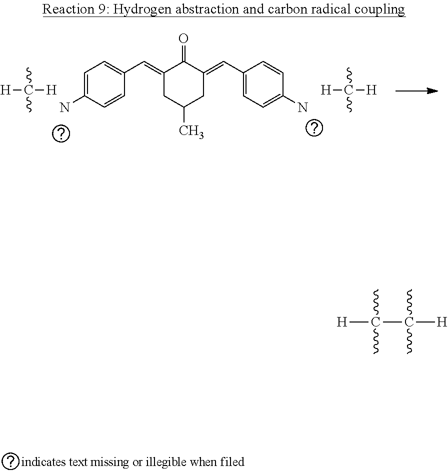

### Example 2: UV-Crosslinking of PVDF-HFP Copolymers with Azide A Crosslinker Component

Two sample mixtures were prepared to test the mechanical stability of PVDF-HFP with Azide A crosslinker component. Samples 3 and 4 were prepared similarly as sample 2, described above. For example, PVDF-HFP was dissolved in MEK and Azide A was dissolved in DCM, with the two solutions being combined and subsequently spin-coated onto a glass substrate. Thereafter, samples 3 and 4 were exposed to UV light for 30 min in N₂ atmosphere and then soaked in MEK overnight. Preparation conditions are summarized in Table 4.

TABLE 4

| | Sample 3 | | Sample 4 | |
|---|---|---|---|---|
| PVDF-HFP | 0.5 | g (Daikin ®) | 0.5 | g (3M ®) |
| MEK | 3 | mL | 3 | mL |
| Azide A | 10% (50 mg) | | 10% (50 mg) | |
| DCM | 2 | mL | 2 | mL |
| Spin coating | 2000 rpm, 60 sec, | | 2000 rpm, 60 sec, | |
| | 2000 rpm/sec | | 2000 rpm/sec | |
| UV irradiation (254 nm) | 30 | min | 30 | min |

| | | |
|---|---|---|
| Soaking (MEK) | overnight | overnight |
| Result | soluble | soluble |

Both samples 3 and 4 were soluble in MEK, indicating that the PVDF-HFP was not crosslinked effectively with Azide A as a crosslinker under UV light in nitrogen atmosphere. FIG. 2 illustrates solubility results of soaking sample 3 and sample 4 in MEK overnight.

Based on the solubility of samples 3 and 4 in MEK, the insertion reaction of nitrene intermediates into carbon-hydrogen bonds alone was not sufficient to provide mechanically stable, crosslinked dielectric layers suitable for use in OTFTs. Thus, to achieve fluoroelastomers containing tunable unsaturation of PVDF-HFP, an organic base was added; the combination of the azide crosslinker component with the organic base is necessary to effectively crosslink PVDF-HFP.

Samples 5-8 were prepared to test the efficacy of using PVDF-HFP with 1,5-diazabicyclo[5.4.0]undec-5-ene (DBU) organic base and Azide A. Preparation conditions are summarized in Table 5.

TABLE 5

| | Sample 5 | | Sample 6 | | Sample 7 | | Sample 8 | |
|---|---|---|---|---|---|---|---|---|
| PVDF-HFP | 0.5 | g | 0.5 | g | 0.5 | g | 0.5 | g |
| DBU | 3% (15 mg) | | 3% (15 mg) | | 3% (15 mg) | | — | |
| MEK | 4 | mL | 4 | mL | 4 | mL | 4 | mL |
| Azide A | 4% (20 mg) | | 4% (20 mg) | | — | | 4% (20 mg) | |
| Chloroform | 1 | mL | 1 | mL | 1 | mL | 1 | mL |
| Spin coating | 1000 rpm, 60 sec, 1000 rpm/sec | | | | | | | |
| UV irradiation | 10 | min | — | | 10 | min | 10 | min |
| (254 nm) | | | | | | | | |

| | | | | |
|---|---|---|---|---|
| Soaking (MEK) | overnight | overnight | overnight | overnight |
| Result | insoluble | soluble | soluble | soluble |

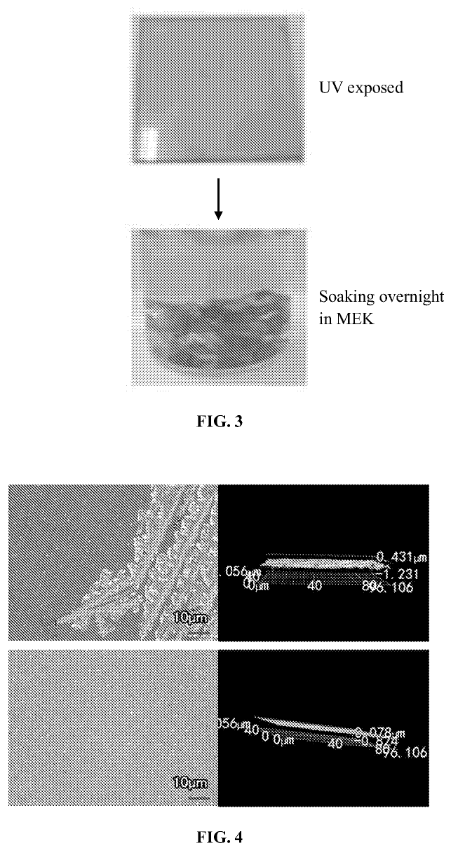

As is shown in Table 5 and FIG. 3, only sample 5, which had each of the organic base, crosslinker component, and exposure to UV light, was insoluble after soaking in MEK overnight. Samples 6, 7, and 8 were prepared to test the necessity for UV light exposure, crosslinker component and organic base, respectively. Lack of any one of these components results in ineffective crosslinking, as measured by the solubility results.

### Example 3: Optimization of UV-Crosslinking of PVDF-HFP Copolymers with Azide A Crosslinker Component

Based on the results of mechanical stability of samples 5-8 and the need for an organic base, crosslinker component, and exposure to UV light, samples 9-24 were prepared with varying amounts of each to determine an optimized crosslinking formulation when using DBU organic base and Azide A crosslinker component. The results are summarized in Table 6.

TABLE 6

| Sample | DBU | | UV | | |
|---|---|---|---|---|---|
| No. | [wt. %] | Azide A [wt. %] | time (min) | Solvent | Result |
| 9 | 1 | 10 | 30 | MEK | Soluble |
| 10 | 2 | 10 | 30 | MEK | Swelling |
| 11 | 3 | 10 | 30 | MEK | Insoluble |
| 12 | 4 | 10 | 30 | MEK | Insoluble |
| 13 | 5 | 10 | 30 | MEK | Insoluble |
| 14 | 3 | 2 | 30 | MEK | Swelling |
| 15 | 3 | 4 | 30 | MEK | Insoluble |
| 16 | 3 | 6 | 30 | MEK | Insoluble |
| 17 | 3 | 8 | 30 | MEK | Insoluble |
| 18 | 3 | 10 | 30 | MEK | Insoluble |
| 19 | 3 | 4 | 5 | MEK | Soluble |
| 20 | 3 | 4 | 10 | MEK | Insoluble |
| 21 | 3 | 4 | 15 | MEK | Insoluble |
| 22 | 3 | 4 | 20 | MEK | Insoluble |
| 23 | 3 | 4 | 25 | MEK | Insoluble |
| 24 | 3 | 4 | 10 | THF | Insoluble |

Based on the solubility results of Table 6, it was determined that a DBU concentration of at least 2 wt. % (e.g., 2 wt. % to 4 wt. %), an Azide A concentration of at least 2 wt. % (e.g., 2 wt. % to 4 wt. %), and a UV light exposure time of at least 10 min was sufficient to achieve effective crosslinking of PVDF-HFP. The roughness of the crosslinked PVDF-HFP film was lower with THF as the organic solvent because Azide A is insoluble in MEK.

Concentration, dissolve time, mixture stirring time and spin coating conditions were also tested to determine their contribution to surface roughness and thickness of the crosslinked film. Roughness and film thicknesses were characterized for samples 25-30 by confocal layer scanning microscope (CLSM) and summarized in Table 7.

TABLE 7

| | Sample 25 | Sample 26 | Sample 27 | Sample 28 | Sample 29 | Sample 30 |
|---|---|---|---|---|---|---|
| PVDF-HFP | 0.5 g | 0.5 g | 0.5 g | 0.5 g | 0.5 g | 0.5 g |
| DBU | 3% | 3% | 3% | 2.5% | 3% | 3% |
| THF | 6 mL | 6 mL | 7 mL | 7 mL | 7 mL | 7 mL |
| Azide A | 4% | 4% | 4% | 3% | 3% | 2.5% |
| Spin coating (60 sec) | 1500 rpm | 2000 rpm | 1500 rpm | 1500 rpm | 1500 rpm | 1500 rpm |
| UV (254 nm) | 10 min | 10 min | 10 min | 10 min | 10 min | 10 min |
| Roughness (Sa, μm) | 0.037 | 0.041 | 0.043 | 0.034 | 0.038 | 0.022 |
| Thickness (μm) | 1.337 | 1.206 | 1.057 | 1.014 | 0.957 | 0.991 |

Table 7 shows that selection of DBU and Azide A content and UV exposure time as determined in Table 6 may yield a roughness in a range of about 0.035 μm to 0.045 μm, with the one exception for Sample 30.

### Example 4: UV-Crosslinking and Optimization of PVDF-HFP Copolymers with 1,3,5-tris(azidomethyl)-2,4,6-triethyl benzene (“Azide B”) Crosslinker Component

UV crosslinking and optimization was also conducted using Azide B. The solubility of Azide B is higher than Azide A in MEK and THF. Using similar preparatory techniques described above and below, samples 31 and 32 were characterized for surface roughness and thickness by CLSM and summarized in Table 8.

TABLE 8

| | Sample 31 | | Sample 32 | |
|---|---|---|---|---|
| PVDF-HFP | 0.5 | g | 0.5 | g |
| DBU | 3% | | 3% | |
| MEK | 6 | mL | 6 | mL |
| Azide B | 6% | | 8% | |
| Spin coating | 1500 rpm, 60 sec, 1500 | | 1500 rpm, 60 sec, 1500 | |
| | rpm/sec | | rpm/sec | |
| UV (254 nm) | 10 | min | 10 | min |

| | | |
|---|---|---|
| Roughness (Sa, μm) | 0.024 | 0.015 |
| Thickness (μm) | 1.327 | 1.465 |

In Table 8, when comparing samples 31 and 32 with samples 25-27, 29, and 30 (having equivalent DBU contents (3 wt. %) and UV exposure times (10 min)), sample 31 and 32 may be deposited as a thicker film with a lower surface roughness (average of 0.020 versus 0.036 for samples 25-27, 29, and 30 (0.040 for just samples 25-27 and 29)). Moreover, FIG. 4 illustrates images of crosslinked PVDF-HFP films with Azide A as crosslinker in THF (upper), and images of crosslinked PVDF-HFP films with Azide B as crosslinker in THF (lower). The left images are confocal layer scanning images, with the right images being the corresponding three-dimensional (3D) image. The upper images using Azide A crosslinker is a high roughness film. Though Azide A dissolves well in THF, it crystallizes out on the film after spin coating. The raised area is the crystalline Azide A. The lower images using Azide B crosslinker is a low roughness film. Azide B does not crystallize out on the film after spin coating, thereby giving a smoother surface.

### Example 5: General Fabrication Procedure of Photo-Crosslinked PVDF-HFP Copolymer Gate Dielectrics and OTFT Devices Thereof

Samples comprising an azide crosslinker component (e.g., Azide A or Azide B) and an organic base (e.g., DBU) were prepared in accordance with the following method.

PVDF-HFP was dissolved in THF or MEK. DBU was mixed with THF or MEK. The DBU mixture was slowly added into the PVDF-HFP elastomer solution. The mixture was stirred for 30 minutes. Azide A or Azide B was added into the combined PVDF-HFP/DBU mixture and then stirred for 20 minutes. After stirring, the PVDF-HFP/DBU/Azide mixture was spun coated on a Si wafer. Photo crosslinking was conducted by exposure of the spun coated films to ultraviolet radiation at either 254 nm or 365 nm using a Hg arc lamp (10 mW). These UV crosslinked PVDF-HFP films with DBU organic base and either Azide A or Azide B crosslinker component were used as gate dielectric materials for OTFT devices.

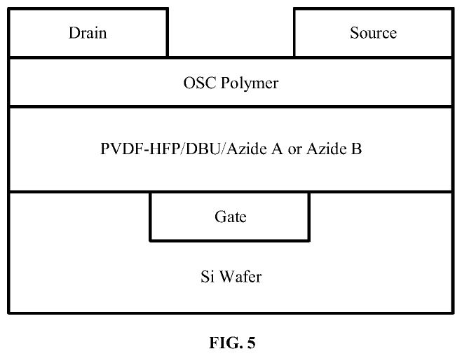

Next, the crosslinked gate dielectric layer was recoated with OSC polymer (at a concentration of 5 mg/mL in m-xylene) at 1000 rpm for 60 sec. After annealing for 60 min at a temperature of about 160° C. in nitrogen atmosphere, electrodes (e.g., Au, 80 nm or Al, 100 nm) were sputtered on both surfaces of the films for electric measurement. FIG. 5 illustrates a final exemplary structure of the OTFT device.

### Example 6: OTFT Device Performance

Table 10 summarizes OTFT performance of devices prepared with and without Azide A. When Azide A is utilized as the crosslinker component, charge mobility increases significantly from 0.831 cm²V⁻¹s⁻¹ to 3.08 cm²V⁻¹s⁻¹, though on/off ratios decrease from 1.49×10³ to 2.26×10¹ due to surface roughness caused by the crystallization of Azide A (see FIG. 4, upper).

TABLE 10

| | Mobility^{LCR} | | | gₘ/W^{avg} |
|---|---|---|---|---|
| Formulation | (cm²V⁻¹s⁻¹) | on/off^{ave} | Vt^{ave} (V) | (μS/cm) |
| PVDF-HFP + DBU | 0.831 ± 0.175 | 1.49 × 10³ | −0.496 ± 0.426 | 51.9 |
| PVDF-HFP + | 3.08 ± 0.61 | 2.26 × 10¹ | 0.434 ± 0.045 | 51.6 |
| DBU + Azide A | | | | |

Table 11 summarizes OTFT performance of devices prepared with varying formulations of Azide B, UV exposure conditions, and organic solvents.

TABLE 11

| | | UV | | Mobility^{LCR} | | | gₘ/W^{avg} |
|---|---|---|---|---|---|---|---|
| Entry | Formulation | exposure | Solvent | (cm²V⁻¹S⁻¹) | on/off^{ave} | Vt^{ave} (V) | (μS/cm) |
| 1 | 2% Azide B | none | THF | 0.731 ± 0.036 | 1.60 × 10⁴ | 0.09 ± 0.046 | 7.48 ± 0.84 |
| 2 | 2% Azide B | 254 nm | THF | 1.63 ± 0.98 | 2.77 × 10² | 0.793 ± 0.127 | 17.3 ± 2.16 |
| 3 | 2% Azide B | 365 nm | THF | 0.729 ± 0.065 | 1.59 × 10⁴ | 0.388 ± 0.114 | 8.52 ± 0.08 |
| 4 | 3% Azide B | none | THF | 0.381 ± 0.116 | 7.58 × 10³ | 0.01 ± 0.293 | 26.9 ± 13.9 |
| 5 | 3% Azide B | 254 nm | THF | 0.478 ± 0.019 | 2.00 × 10⁴ | 0.091 ± 0.109 | 26.8 ± 24.8 |
| 6 | 3% Azide B | 365 nm | THF | 0.889 ± 0.023 | 7.14 × 10³ | −0.239 ± 0.069 | 8.61 ± 0.33 |
| 7 | 6% Azide B | 254 nm | THF | 1.748 ± 0.524 | 3.44 × 10¹ | −0.426 ± 0.206 | 23.3 ± 4.94 |
| 8 | 6% Azide B | 254 nm | MEK | 1.785 ± 0.524 | 8.94 × 10¹ | 0.104 ± 0.286 | 22.3 ± 1.11 |
| 9 | 6% Azide B | 365 nm | THF | 1.420 ± 0.264 | 9.22 × 10³ | −0.101 ± 0.020 | 28.2 ± 2.68 |
| 10 | 6% Azide B | 365 nm | MEK | 2.372 ± 0.314 | 9.63 × 10¹ | 0.254 ± 0.397 | 24.2 ± 2.73 |
| 11 | 8% Azide B | 254 nm | THF | 2.082 ± 0.649 | 4.88 × 10¹ | −0.662 ± 0.143 | 25.1 ± 5.14 |
| 12 | 8% Azide B | 254 nm | MEK | 0.808 ± 0.055 | 4.80 × 10³ | −0.472 ± 0.115 | 11.1 ± 1.61 |
| 13 | 8% Azide B | 365 nm | THF | 3.789 ± 0.946 | 3.00 × 10⁴ | 0.106 ± 0.028 | 31.4 ± 0.83 |
| 14 | 8% Azide B | 365 nm | MEK | 1.041 ± 0.123 | 5.35 × 10³ | −0.025 ± 0.066 | 15.2 ± 1.39 |

Crosslinked films prepared with Azide B may have high charge mobility above 3.0 cm²V⁻¹s⁻¹ (e.g., 3.789 cm²V⁻¹s⁻¹). For example, OTFT devices manufactured with UV curing under 365 nm are mostly characterized by higher on/off ratio, even at high ratios of Azide B. In comparison, the on/off ratios were significantly lower if the gate dielectric layers were cured under 254 nm. This may be due to material/device damage caused by high energy UV length at 254 nm.

Regarding the relationship between azide ratio and transconductance, higher azide ratio corresponds to higher device performance (see entry 3, 6, 9, 13 for 365 nm; entry 2, 5, 7, 11 for 254 nm), but with much more profound effect in case of 365 nm.

Solvent effects are also significant, especially when azide ratio is high (see entry 11-14). For example, THF provides better OTFT performance than MEK, though spin-coated films obtained with MEK appear to have better surface quality.

In one example (entry 13), where the OTFT was prepared with 8 wt. % Azide B under 365 nm in THF, charge mobility was improved to 3.789 cm²V⁻¹s⁻¹ and the on/off ratio was high at 3.00×10⁴. Additionally, steady threshold voltages and high transconductances aide to obtain stable devices for mass industrial production.

Thus, as presented herein, a UV-crosslinkable gate dielectric insulator formulation and method of fabricating thereof is disclosed comprising PVDF-based polymers, at least one organic base and azide-based crosslinker components as part of OTFT devices having superior electrical performance.

Advantages of the UV crosslinking method of forming the OTFT device include: (1) avoiding using complicated and non-environmental friendly photolithography, providing less steps and low-cost methods for fabricating patterned parts in micro-electronic devices; (2) taking less a shortened time (e.g., 10 min) with low lamp power (e.g., 10 mW/cm²) without the need for heating; and (3) being more controllable than thermal crosslinking. The surface quality of the gate dielectric film is significantly improved with a lowered surface roughness and this smoother surface film will directly improve electronic performance of OTFT devices. Advantages of the UV-crosslinked PVDF-HFP film include (1) a preserved double-layer capacitor effect, thereby being a promising candidate as gate dielectric insulators for portable high-current output OTFT devices, such as flexible OLED displays; and (2) offering higher charge mobilities, transconductance, and on/off ratios (e.g., on the order of 1-2 orders of magnitude).

The disclosed UV crosslinking methods based on azide crosslinkers or UV radical initiator/crosslinker systems may also be applied in curing dielectric/insulating polymers and OSC polymers with C═C double bonds or active C—H bonds as curing sites; or to polymers that readily generate these curing sites before or in-situ the UV curing processes.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

As utilized herein, “optional,” “optionally,” or the like are intended to mean that the subsequently described event or circumstance can or cannot occur, and that the description includes instances where the event or circumstance occurs and instances where it does not occur. The indefinite article “a” or “an” and its corresponding definite article “the” as used herein means at least one, or one or more, unless specified otherwise.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be apparent to those skilled in the art that various modifications and variations can be made without departing from the spirit or scope of the claimed subject matter. Accordingly, the claimed subject matter is not to be restricted except in light of the attached claims and their equivalents.

What is claimed is:

1. A method, comprising:
preparing a mixture comprising: an organic solvent, a fluorine-containing polymer, at least one organic base, and a crosslinker component;
depositing the mixture over a substrate to form a first layer;
crosslinking the first layer by light treatment to form a crosslinked gate dielectric layer,
wherein the fluorine-containing polymer is at least one of homopolymers of vinylidene fluoride, copolymers of vinylidene fluoride with fluorine-containing ethylenic monomers, or a combination thereof.

2. The method of claim 1, wherein the fluorine-containing polymer is a copolymer of vinylidene fluoride with at least one fluorine-containing ethylenic monomers.

3. The method of claim 2, wherein the at least one fluorine-containing ethylenic monomers are represented by Formula (1) or Formula (2):
CF₂═CF—R_{f1} (Formula 1)
wherein:
R_{f1} is selected from: —F; —CF₃; and —OR_{f2}; and
R_{f2} is a perfluoroalkyl group having 1 to 5 carbon atoms;
CX₂═CY—R_{f3} (Formula 2)
wherein:
X is —H, or —F, or a halogen atom;
Y is —H, or —F, or a halogen atom; and
R_{f3} is —H, or —F, a perfluoroalkyl group having 1 to 5 carbon atoms, or a polyfluoroalkyl group having 1 to 5 carbon atoms.

4. The method of claim 2, wherein the at least one fluorine-containing ethylenic monomers are selected from: tetrafluoroethylene (TFE), chlorotrifluoroethylene (CTFE), trifluoroethylene, hexafluoropropylene (HFP), trifluoropropylene, tetrafluoropropylene, pentafluoropropylene, trifluorobutene, tetrafluoroisobutene, perfluoro(alkyl vinyl ether) (PAVE), and combinations thereof.

5. The method of claim 1, wherein the fluorine-containing polymer is poly(vinylidene fluoride-co-hexafluoropropylene) (PVDF-HFP).

6. The method of claim 1, wherein the at least one organic base has the structure: 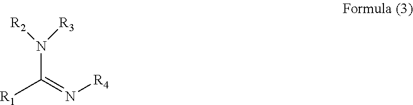
wherein:
the at least one organic base has a molecular weight of 1000 or less;
R₁ and R₂ form a C₂-C₁₂ alkylene bridge, or independently of one another are C₁-C₁₈ alkyls;
R₃ and R₄, independent from R₁ and R₂, form a C₂-C₁₂ bridge, or independently of one another are C₁-C₁₈ alkyls.

7. The method of claim 6, wherein the at least one organic base is selected from: 1,8-diazabicyclo[5.4.0]undec-7-ene, (DBU); 1,5-diazabicyclo[4.3.0]non-5-ene, (DBN); tetramethylguanidine, (TMG); triethylamine, (TEA); hexamethylenediamine, (HMDA); methylamine; dimethylamine; ethylamine; azetidine; isopropylamine; propylamine; 1.3-propanediamine; pyrrolidine; N,N-dimethylglycine; butylamine; tert-butylamine; piperidine; choline; hydroquinone; cyclohexylamine; diisopropylamine; saccharin; o-cresol; δ-ephedrine; butylcyclohexylamine; undecylamine; 4-dimethylaminopyridine (DMAP); diethylenetriamine; 4-aminophenol; or combinations thereof.

8. The method of claim 1, wherein the crosslinker component is an aryl azide.

9. The method of claim 8, wherein the aryl azide comprises: 2,6-bis(4-azidobenzylidene) cyclohexanone; 1,3,5-tris(azidomethyl)-2,4,6-triethyl benzene; phenyl azide; o-hydroxyphenyl azide; m-hydroxyphenyl azide; tetrafluorophenyl azide; o-nitrophenyl azide; m-nitrophenyl azide; azido-methyl coumarin; N-(5-azido-2-nitrobenzoyloxy) succinimide; N-hydroxysuccinimidyl-4-azidobenzoate; p-azidophenacyl bromide; 4-azido-2,3,5,6-tetrafluorobenzoic acid; N-succinimidyl 4-azido-2,3,5,6-tetrafluorobenzoate; bis[2-(4-azidosalicylamido)ethyl] disulfide; 2-[N2-(4-azido-2,3,5,6-tetrafluorobenzoyl)-N6-(6-biotinamidocaproyl)-L-lysinyflethyl 2-carboxyethyl disulfide; 2-[N2-(4-azido-2,3,5,6-tetrafluorobenzoyl)-N6-(6-biotinamidocaproyl)-L-lysinyl]ethyl methanethiosulfonate; 2-{N2-[N6-(4-Azido-2,3,5,6-tetrafluorob enzoyl)-6-aminocaproyl] -N6-(6-biotinamidocaproyl)-L-lysinylamido}] ethyl 2-carboxyethyl disulfide; 2-{N2-[N6-(4-azido-2,3,5,6-tetrafluorobenzoyl)-6-aminocaproyl]-N6-(6-biotinamidocaproyl)-L-lysinylamido}ethyl methanethiosulfonate; 2-[N2-(4-azido-2,3,5,6-tetrafluorobenzoyl)-N6-(6-biotinamidocaproyl)-L-lysinyl]ethyl 2′-(N-sulfosuccinimidylcarboxy) ethyl disulfide, sodium salt; 6-(4-azido-2-nitrophenylamino)hexanoic acid N-hydroxysuccinimide ester; N-succinimidyl 4-azidosalicylate; sulphosuccinimidyl 6-(4′-azido-2′-nitrophenylamino) hexanoate; S-[2-(4-azidosalicylamido) ethylthio]-2-thiopyridine; S-[2-(iodo-4-azidosalicylamido) ethylthio]-2-thiopyridine; 3-[[2-[(4-azido-2-hydroxybenzoyl)amino]ethyl]dithio]propanoic acid 2,5-dioxo-3-sulfo-1-pyrrolidinyl ester sulfo-N-succinimidyl3-[[2-(p-azidosalicylamido)ethyl]-1,3′-dithio]propionate, or combinations thereof.

10. The method of claim 1, wherein the organic solvent is selected from methyl ethyl ketone (MEK) and tetrahydrofuran (THF).

11. The method of claim 1, wherein the crosslinking the first layer by light treatment comprises:
exposing the first layer to ultraviolet (UV) light for a time in a range of 10 sec to 60 min.

12. The method of claim 1, wherein the crosslinking the first layer by light treatment comprises:
exposing the first layer to ultraviolet (UV) light to a total energy in a range of 5 J to 2600 J.

13. The method of claim 1, further comprising:
depositing an organic semiconductor over the substrate to form a second layer, the second layer being in direct contact with the crosslinked gate dielectric layer;
forming a source and a drain in contact with the second layer, the source and drain defining the ends of a channel through the second layer; and
forming a gate superposed with the channel to form a transistor,
wherein the crosslinked gate dielectric layer separates the gate from the second layer.

14. A transistor, comprising:
a substrate;
a crosslinked gate dielectric layer disposed over the substrate;
an organic semiconductor layer disposed over the substrate, the organic semiconductor layer being in direct contact with the crosslinked gate dielectric layer;
a source and a drain in contact with the organic semiconductor layer the source and drain defining the ends of a channel through the organic semiconductor layer; and
a gate superposed with the channel,
wherein the crosslinked gate dielectric layer separates the gate from the organic semiconductor layer.

15. The transistor of claim 14, wherein the crosslinked gate dielectric layer comprises:
at least one organic base at a concentration in a range of 0.01 wt. % to 10 wt. %; and
a crosslinker component at a concentration in a range of 0.01 wt. % to 10 wt. %.

16. The transistor of claim 15, wherein the at least one organic base is at a concentration in a range of 1 wt. % to 5 wt. % and the crosslinker component is at a concentration in a range of 2 wt. % to 8 wt. %.

17. (canceled)

18. The transistor of claim 14, wherein the crosslinked gate dielectric layer is configured to have a surface roughness in a range of 0.01 μm to 0.05 μm.

19. The transistor of claim 14, configured to have a charge mobility of at least 3.0 cm²V⁻¹s⁻¹.

20. The transistor of claim 14, configured to have an average on/off ratio of at least 3.00×10⁴.

21. The transistor of claim 14, wherein the crosslinked gate dielectric layer comprises one of a 2,6-bis(4-azidobenzylidene) cyclohexanone or 1,3,5-tris(azidomethyl)-2,4,6-triethyl benzene crosslinker component and at least one organic base.
